(19) United States
(12) Patent Application Publication
(10) Pub. No.: US 2010/0201347 A1
(43) Pub. Date: Aug. 12, 2010

(54) VOLTAGE MEASURING DEVICE AND STORAGE DEVICE

(75) Inventors: Masaharu MORITSUGU, Sagamihara-shi (JP); Hiroki MATSUSHITA, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOSHIBA STORAGE DEVICE CORPORATION, Tokyo (JP)

(21) Appl. No.: 12/696,939

(22) Filed: Jan. 29, 2010

(30) Foreign Application Priority Data
Jan. 29, 2009 (JP) 2009-017505

(51) Int. Cl. G01R 19/155

(52) U.S. Cl. 324/128

(57) ABSTRACT

According to one embodiment, a voltage measuring device that measures an input voltage signal includes a divider, a filter, an adder, and an analog-to-digital converter. The divider divides the input voltage signal into a first signal and a second signal. The filter filters the first signal and attenuates a direct current component of the first signal less than a predetermined frequency component of an alternating current component of the first signal. The adder adds an output signal of the filter to the second signal. The analog-to-digital converter converts an output signal of the adder into a digital signal. The divider adjusts the amplitude of at least one of the first signal and the second signal such that the level of a direct current component of the output signal of the adder is in the input range of the analog-to-digital converter.

### CROSS-REFERENCE TO RELATED APPLICATIONS

This application is based upon and claims the benefit of priority from Japanese Patent Application No. 2009-017505, filed Jan. 29, 2009, the entire contents of which are incorporated herein by reference.

### BACKGROUND

1. Field

One embodiment of the invention relates to a voltage measuring device that measures an input voltage signal and a storage device.

2. Description of the Related Art

In general, a magnetic disk device comprises a voltage measuring module (VM) 43 that reads a change in voltage supplied from the outside. FIG. 7 is a circuit diagram illustrating an example of the configuration of the voltage measuring module 43. The voltage measuring module 43 divides a supply voltage Vcc (5 V) by resistances R1 and R2, adjusts the voltage in a range of an A/D converter 51, and reads the voltage. The resistances R1 and R2 cause the supply voltage divided by the resistances to be adjusted in a dynamic range of the A/D converter 51.

One reason why the supply voltage is read is to previously prevent hardware reset from being generated due to a decrease in the supply voltage. When the supply voltage is lower than the lower limit of a predetermined supply voltage, the magnetic disk device performs hardware reset. If the hardware reset occurs during write of data, the data cannot be read. To prevent the data from not being read, when the voltage measuring module measures the supply voltage and determines that the supply voltage is lower than a predetermined write stop voltage slightly higher than the lower limit of the supply voltage, firmware (FW) stops a write operation.

Another reason why the supply voltage is read is to discriminate between erroneous detection of a shock sensor generated due to a capacitor vibration caused by a power ripple change and actual detection of a shock generated due to an external vibration.

The reasons will be described in detail below.

In the conventional magnetic disk device, a shock sensor (SS) is mounted on a printed circuit board assembly (PCBA), and is connected to a micro control unit (MCU) through a shock sensor amplifier in a servo controller (SVC). When a vibration of a predetermined value or more is applied from the outside, the MCU stops a recording operation according to a signal from the shock sensor not to record incorrect data on adjacent tracks (protect the tracks).

If a shock is received from the outside, the shock sensor responds to the shock and generates a charge proportional to a G value. FIG. 8 is a circuit diagram illustrating an example of the configuration of a shock sensor amplifier (SSA) 42. The shock sensor amplifier 42 comprises a charge amplifier 61 and a window comparator 62. The charge amplifier 61 is located at a subsequent stage of a shock sensor 15 and converts the charge into a voltage.

FIG. 9 is a timing chart illustrating an example of the operation at the time the magnetic disk device receives a shock. FIG. 9 sequentially illustrates waveforms of a Write GATE, a FAULT signal, an output from the shock sensor 15, and a shock, from an uppermost stage.

The window comparator 62 compares a voltage value after a conversion by the charge amplifier 61 with the predetermined detection width (lower and upper limits). When it is determined that the shock exceeding the detection width is applied, the window comparator 62 transmits the FAULT signal to the MCU. The MCU that has received the FAULT signal stops a recording operation by interruption of the hardware (drops the Write GATE). By this operation, data corruption of adjacent tracks is prevented.

For example, Japanese Patent Application Publication (KOKAI) Nos. 2001-266466, 11-126412, 2007-149299, 9-97401, and 2005-4907 disclose conventional technologies for controlling the magnetic disk device using the shock sensor.

However, when disturbance is not generated, the recording operation may be stopped due to erroneous detection of the shock.

To prevent change of power, a laminated ceramic capacitor that has a large capacity in a range of 10 μF to 20 μF is mounted on the PCBA. Because of a flow of charges due to a power change (ripple) caused by recent thin film lamination, the capacitor may cause a self vibration. Similarly to a piezo element, if a voltage changes, the laminated ceramic capacitor causes a mechanical vibration (compression/extension). The mechanical vibration is transmitted to the PCBA and vibrates the shock sensor. In this case, the shock sensor detects the shock, but the magnetic disk device does not receive the vibration. For this reason, a position of a head does not change and the write operation does not need to be stopped. The erroneous detection generated due to the power ripple causes the recording operation to be stopped, thereby deteriorating performance.

FIG. 10 is a timing chart illustrating an example of erroneous detection of a shock. FIG. 10 sequentially illustrates waveforms of a supply voltage Vcc (5 V), an output from the shock sensor 15, a FAULT signal, and a position error signal (PES), from an uppermost stage.

When a line noise (ripple) is applied to the supply voltage Vcc and the amplitude of the output from the shock sensor 15 exceeds the detection width (becomes the predetermined amplitude or more) or a frequency of the applied line noise is matched with a resonance frequency of the shock sensor 15 or a resonance frequency of the PCBA, the shock sensor amplifier 42 performs erroneous detection even though the line noise is a low voltage (200 mV or less), and the FAULT is continuously generated. In this case, even though a Write command is issued from an upper apparatus (host), the FAULT is frequently generated. For this reason, a Write process may not be continuously executed and performance may be deteriorated. In this case, since the shock is not directly applied to the magnetic disk device, the FAULT is generated, but a position signal (position information, for example, PES) that corresponds to a track following signal does not fluctuate.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary block diagram of a magnetic disk device;

FIG. 2 is an exemplary flowchart of the process of preventing erroneous shock detection;

FIG. 3 is an exemplary table of a relationship between a manufacture process of an LSI and detection ripple amplitude;

FIG. 4 is an exemplary circuit diagram of the configuration of a voltage measuring module according to a first embodiment of the invention;

FIG. 5 is an exemplary view of a frequency characteristic required in the voltage measuring module in the first embodiment;

FIG. 6 is an exemplary circuit diagram of the configuration of a voltage measuring module according to a second embodiment of the invention;

FIG. 7 is an exemplary circuit diagram of the configuration of a voltage measuring module according to a conventional technology;

FIG. 8 is an exemplary circuit diagram of the configuration of a shock sensor amplifier in the conventional technology;

FIG. 9 is an exemplary timing chart of the operation of when the magnetic disk device receives a shock in the conventional technology; and

FIG. 10 is an exemplary timing chart of erroneous detection of a shock in the conventional technology.

### DETAILED DESCRIPTION

Various embodiments according to the invention will be described hereinafter with reference to the accompanying drawings. In general, according to one embodiment of the invention, a voltage measuring device that measures an input voltage signal comprises a divider, a filter, an adder, and an analog-to-digital converter. The divider is configured to divide the input voltage signal into a first signal and a second signal. The filter is configured to filter the first signal and attenuate a direct current component of the first signal less than a predetermined frequency component of an alternating current component of the first signal. The adder is configured to add an output signal of the filter to the second signal. The analog-to-digital converter is configured to convert an output signal of the adder into a digital signal. The divider is configured to adjust the amplitude of at least one of the first signal and the second signal such that the level of a direct current component of the output signal of the adder is in the input range of the analog-to-digital converter.

According to another embodiment of the invention, a voltage measuring device that measures an input voltage signal comprises a divider, a filter, a subtracter, and an analog-to-digital converter. The divider is configured to divide the input voltage signal into a third signal and a fourth signal. The filter is configured to filter the third signal and attenuate a predetermined frequency component of an alternating current component of the third signal less than a direct current component of the third signal. The subtracter is configured to subtract an output signal of the filter from the fourth signal. The analog-to-digital converter is configured to convert an output signal of the subtracter into a digital signal. The divider is configured to adjust the amplitude of at least one of the third signal and the fourth signal such that the level of a direct current component of the output signal of the subtracter is in the input range of the analog-to-digital converter.

According to still another embodiment of the invention, a storage device that performs a write operation on a storage medium comprises a divider, a filter, an adder, an analog-to-digital converter, a shock sensor, and a controller. The divider is configured to divide an input voltage signal supplied to the storage device into a first signal and a second signal. The filter is configured to filter the first signal and attenuate a direct current component of the first signal less than a predetermined frequency component of an alternating current component of the first signal. The adder is configured to add an output signal of the filter to the second signal. The analog-to-digital converter is configured to convert an output signal of the adder into a digital signal. The shock sensor is configured to detect a shock applied to the storage device. The controller is configured to control the write operation on the storage medium based on an output from the analog-to-digital converter and an output from the shock sensor. The divider is configured to adjust the amplitude of at least one of the first signal and the second signal such that the level of a direct current component of the output signal of the adder is in the input range of the analog-to-digital converter.

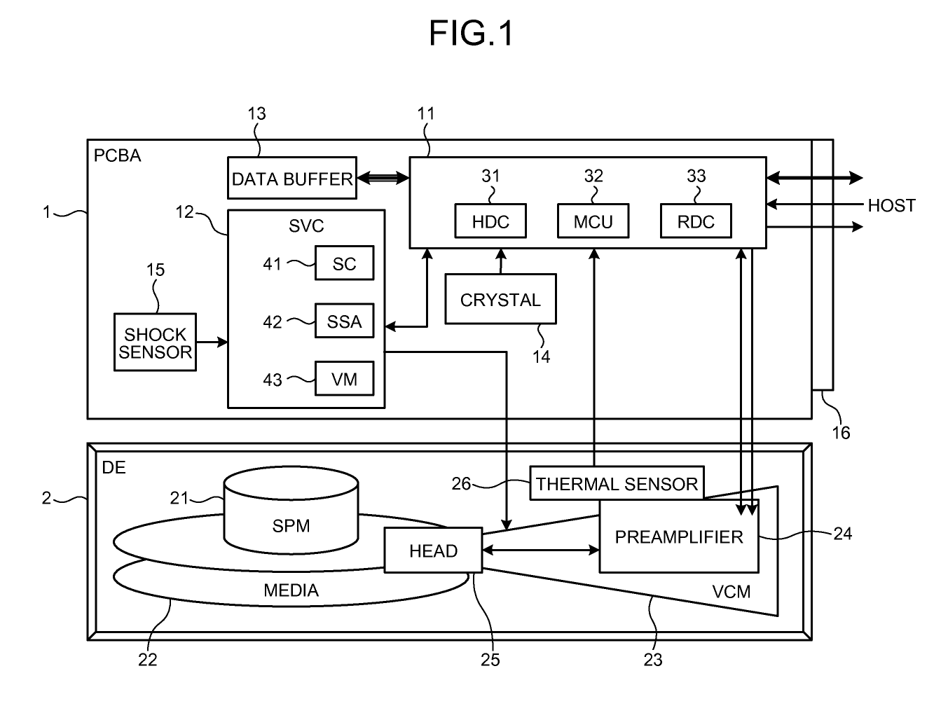

FIG. 1 is a block diagram of an example of the configuration of a magnetic disk device. The magnetic disk device comprises a printed circuit board assembly (PCBA) 1 and a disk enclosure (DE) 2. The PCBA 1 comprises a controller 11, a SVC (Servo Combo) 12, a data buffer 13, a crystal oscillator (Crystal) 14, the shock sensor 15, and a serial ATA interface 16. The DE 2 comprises a spindle motor (SPM) 21, media (storage media) 22, a voice coil motor (VCM) 23, a preamplifier 24, a head 25, and a thermal sensor 26. The controller 11 comprises a hard disk controller (HDC) 31, a micro control unit (MCU) 32, and a read channel (RDC) 33. The SVC 12 comprises a servo controller (SC) 41, the shock sensor amplifier (SSA) 42, and the voltage measuring module (VM) 43.

The controller 11 controls various modules according to a command received from the host through the serial ATA interface 16 and a clock generated by the crystal oscillator 14. The data buffer 13 temporarily stores write data and read data. The servo controller 41 controls the SPM 21 and the VCM 23 according to an instruction from the controller 11. The shock sensor amplifier 42 determines whether the shock is generated based on an output from the shock sensor 15.

The SPM 21 rotates the media 22. The VCM 23 moves the head 25. The preamplifier 24 amplifies a Write signal input to the head 25 and a read signal output from the head 25. The thermal sensor 26 measures the temperature of a peripheral portion of the head 25. A description will be given of the process of preventing erroneous shock detection based on FW by using the conventional voltage measuring module instead of the voltage measuring module 43.

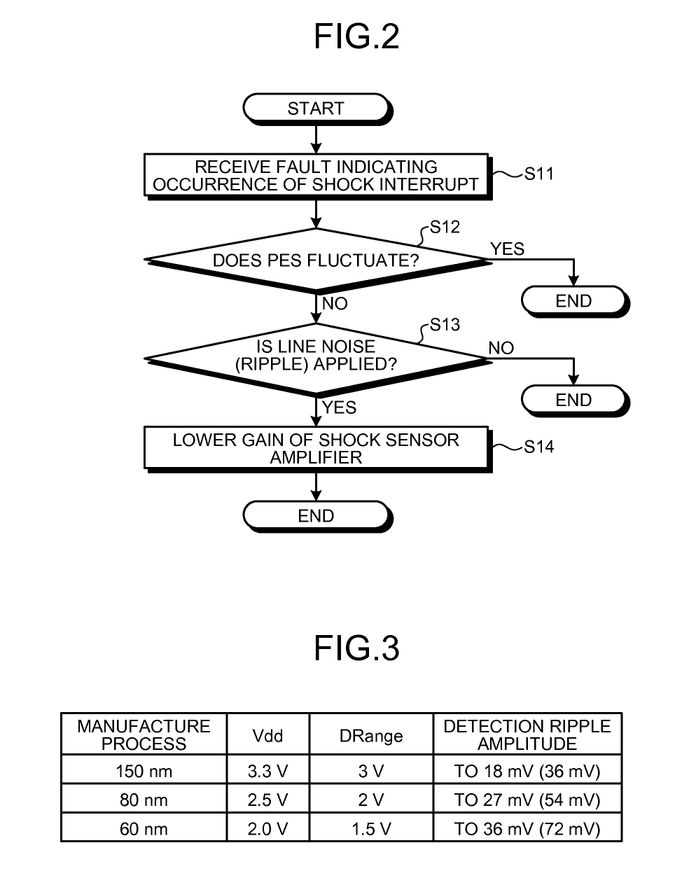

The FW is executed by the MCU 32. FIG. 2 is a flowchart of an example of the process of preventing erroneous shock detection. If the MCU 32 receives a FAULT from the shock sensor amplifier 42 (shock interrupt occurs) (S11), the RDC 33 detects a PES from the read signal and the MCU 32 determines whether the PES fluctuates (S12). When it is determined that the PES fluctuates (YES at S12), the process ends. When it is determined that the PES does not fluctuate (NO at S12), the MCU 32 detects a change in output from the voltage measuring module 43 and determines whether a line noise (power ripple) is applied to supply power (S13). When it is determined that the line noise is not applied to the supply power (NO at S13), the process ends. When it is determined that the line noise is applied to the supply power (YES at S13), the MCU 32 lowers the gain of the shock sensor amplifier 42 (S14), and the process ends.

That is, when the FW detects that the following condition is realized, the FW determines the detection as erroneous shock detection due to the line noise (power ripple), lowers the gain of the shock sensor amplifier 42 to suppress the shock interrupt (FAULT) from being generated, and causes a write operation to be continuously performed.

Condition=((fluctuation of a power supply voltage) AND (generation of FAULT)) AND (NOT (normal position error))

In this case, the “normal position error” means that the PES does not fluctuate. To prevent the generation of the erroneous shock detection due to the line noise, the MCU 32 reads the change (ripple) applied to the power by the voltage measuring module. The A/Din input to the A/D converter 51 is adjusted in a dynamic range of the A/D converter 51 by resistances R1 and R2.

A/Din=R1/(R1+R2)×Vcc

In this case, it is assumed that the A/D converter 51 has a resolution of 8 bits. In a 150 nm process, a dynamic range of the A/D converter 51 is about 3 V. When the supply voltage 5 V is adjusted to the center of the dynamic range of the A/D converter 51, the resolution of the A/D converter 51 is about 6 mV. In the supply voltage, the detection ripple amplitude that is the actual amplitude of ripples to be detected is represented by the following equation.

Detection ripple amplitude=resolution of the A/D converter 51×(R1+R2)/R2

In this case, the detection ripple amplitude is about 18 mV.

Meanwhile, as a recording density of an HDD increases, since a calculation speed required in the MCU and a transmission speed of the RDC (Read Channel) need to increase and power consumption needs to decrease, the process of the LSI changes to a high-density process. Specifically, the density increases in the order of 150 nm→80 nm→60 nm→ . . . . With the advancement of process, a voltage supplied to the LSI also decreases in the order of 3.3 V→2.5 V→2.0 V→ . . . . The dynamic range of the A/D converter 51 is reduced in a form of being proportional to the voltage supplied to the LSI. However, the amplitude of the ripple applied to the A/D converter 51 is also reduced and may not be detected when the amplitude becomes the resolution or less.

FIG. 3 is a table illustrating an example of a relationship between a manufacture process of the LSI and the detection ripple amplitude. This table illustrates a manufacture process of the LSI, a voltage Vdd supplied to the LSI, a dynamic range DRange of the A/D converter 51, and detection ripple amplitude. The detection ripple amplitude in parentheses is a value obtained by anticipating the double detection ripple amplitude, on the grounds that the precision of the A/D converter 51 is generally ±1 LSB.

As described above, due to an increase in the density of the manufacture process and a decrease in the detection ripple amplitude, it becomes difficult to implement the erroneous shock detection prevention based on the FW. The detection ability required for the erroneous shock detection prevention is predicted as a range of 50 to 100 mV, and the limit of the manufacture process is predicted as an 80 nm process.

The configuration of a magnetic disk device according to a first embodiment of the invention will be described with reference to FIG. 1. The magnetic disk device of the first embodiment is of basically the same configuration as illustrated in FIG. 1 except the presence of a voltage measuring module (VM) 43a instead of the voltage measuring module 43.

The voltage measuring module 43a performs an amplifying operation at a previous stage of the A/D converter 51. Since the voltage measuring module 43a measures a change in voltage supplied from the outside, gain of a DC component of the supply voltage is set to one time. Gain of an AC component of the supply voltage is set to be larger than one time.

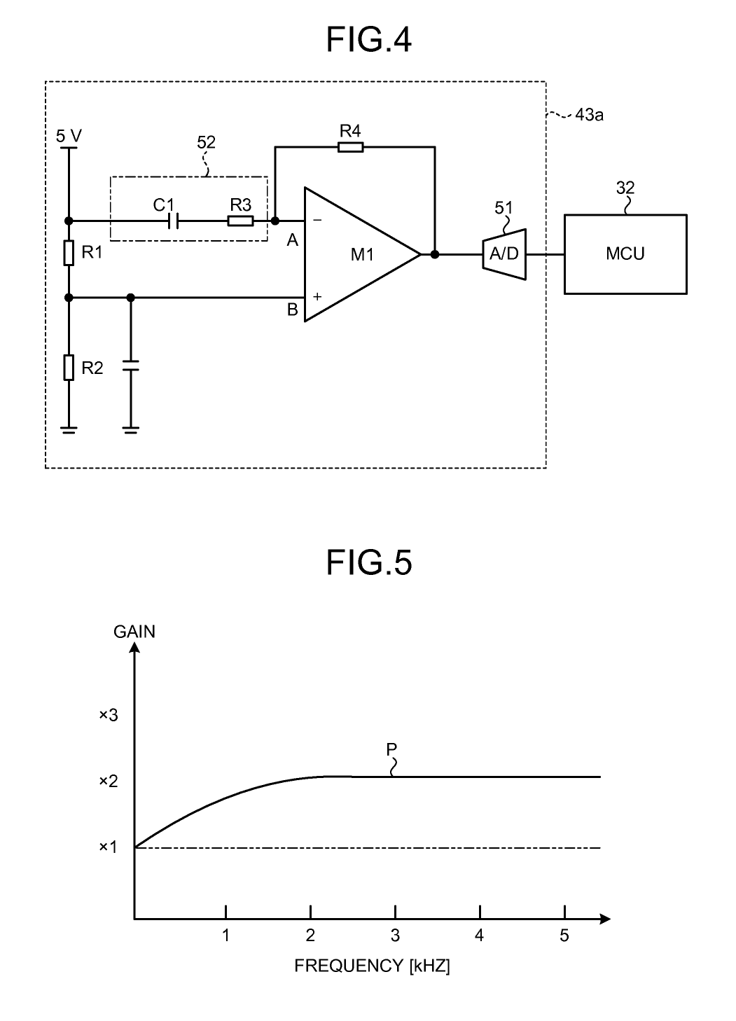

FIG. 4 is a circuit diagram of an example of the configuration of the voltage measuring module 43a. In this case, the supply voltage Vcc (input voltage signal) is set to 5 V. A voltage of a point A is set to VA (first signal) and a voltage of a point B is set to VB (second signal). The voltage measuring module 43a comprises an HPF 52 having a cutoff frequency fc determined by capacitance C1 and resistance R3.

The voltage measuring module 43a divides the supply voltage Vcc by the resistances R1 and R2. If the supply voltage Vcc is made to pass through the HPF 52, the voltage VA is obtained. If the supply voltage Vcc is divided by the resistances, the voltage VB is obtained. The voltages VA and VB are added to the voltage Vdc by an amplifier (differential amplifier) M1 (corresponding to an adder), and an addition result is input to the A/D converter 51. A resistance voltage division ratio or an amplification factor by the amplifier M1 is selected such that the DC component of the supply voltage Vcc is adjusted to about the center of the dynamic range of the A/D converter 51.

FIG. 5 illustrates an example of a frequency characteristic required in the voltage measuring module 43a. In FIG. 5, a characteristic P indicates a frequency characteristic of the gain of the voltage measuring module 43a. The voltage measuring module 43a is designed such that the gain of the DC component of the supply voltage becomes one time and the gain of the AC component of the supply voltage becomes larger than one time. As illustrated in the characteristic P, in this example, the gain in 2 kHz or more becomes two times. By the frequency characteristic of the gain, the voltage measuring module 43a can accurately read the DC component, and amplify the AC component to improve detection performance.

The cutoff frequency becomes a servo band or more by the shock sensor and becomes a frequency where the hardware-wise record stopping process (FAULT) is needed due to the disturbance. Therefore, the cutoff frequency is preferably about 1 kHz.

In this case, the DC component of the supply voltage Vcc is set to Vdc and the AC component of the supply voltage Vcc is set to Vac. A voltage A/Din input to the A/D converter is represented by the following simplified Equation 1:

A/Din=VB+VA×R4/R3=Vcc×R1/(R1+R2)+Vac×R4/R3 (1)

In the case of R3=R4, the following Equation 2 is obtained:

A/Din=Vcc×R1/(R1+R2)+Vac=(Vdc+Vac)×R1/(R1+R2)+Vac=Vdc×R1/(R1+R2)+Vac(1+R1/(R1+R2)) (2)

In Equation 2, even when the amplitude of the DC component is reduced by the resistance voltage division, the amplitude of the AC component is not reduced. As a result, the AC component is measured as a value larger than that of the DC component.

A pass band of the HPF 52 has a frequency component of the power ripple, but does not have the DC component. The pass band (cutoff frequency) of the HPF 52 may be determined in consideration of a resonance frequency of the laminated ceramic capacitor, a resonance frequency of the shock sensor, and a resonance frequency of the PCBA.

Any circuit that adds a supply voltage signal and a signal obtained by attenuating the DC component may be used as the configuration other than the voltage measuring module 43a.

A magnetic disk device according to a second embodiment of the invention is of basically the same configuration as that of the first embodiment except the presence of a voltage measuring module (VM) 43b instead of the voltage measuring module 43a.

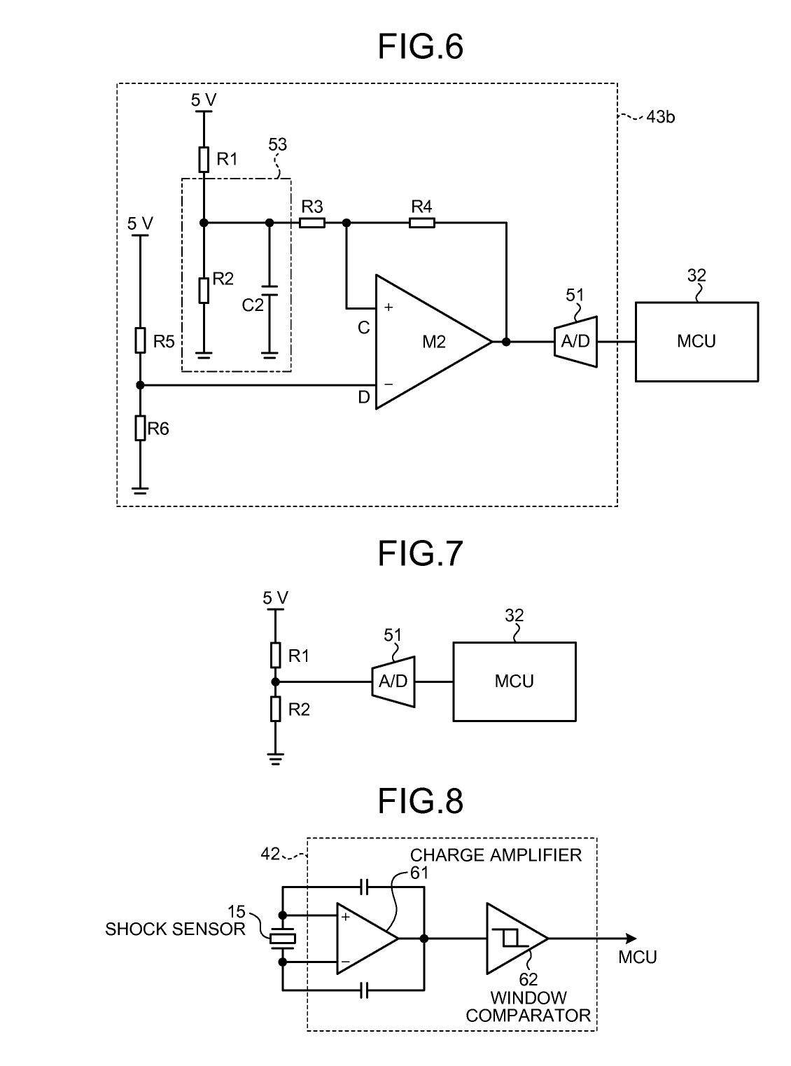

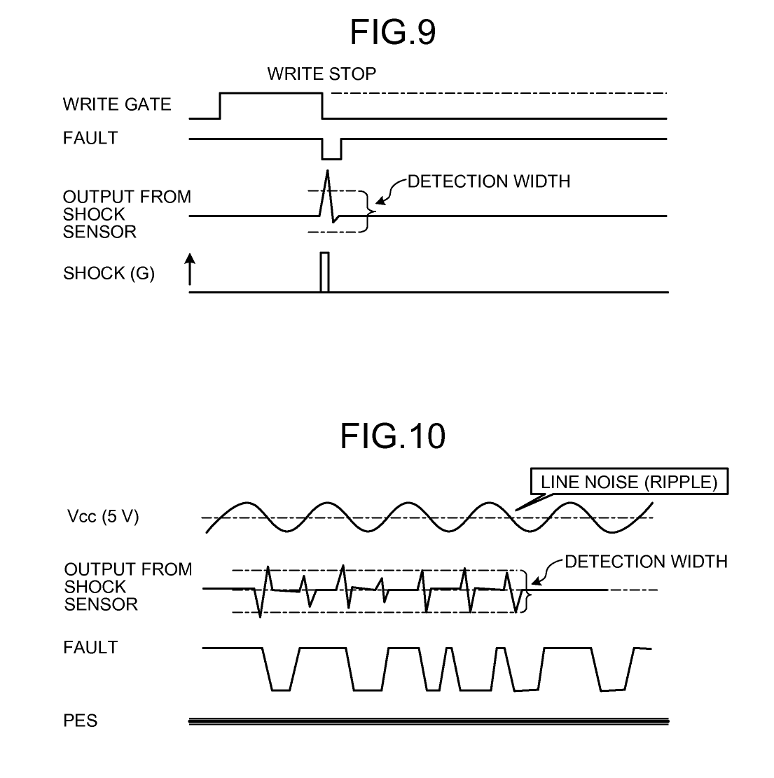

FIG. 6 is a circuit diagram of an example of the configuration of the voltage measuring module 43b. In this case, the supply voltage Vcc is set to 5 V. A voltage at a point C is set to VC (third signal) and a voltage at a point D is set to VD (fourth signal). The voltage measuring module 43a comprises an LPF 53 having a cutoff frequency fc determined by the capacitance C2 and the resistance R2.

The voltage measuring module 43b divides the supply voltage Vcc by the resistances R1 and R2. If the supply voltage Vcc is made to pass through the LPF 53, the voltage VC is obtained. If the supply voltage Vcc is divided by resistances R5 and R6, the voltage VD is obtained. The voltages VC and VD are subtracted by an amplifier (differential amplifier) M2 (corresponding to a subtracter), and a subtraction result is input to the A/D converter 51. A resistance voltage division ratio or an amplification factor by the amplifier M2 is selected such that the DC component of the supply voltage Vcc is adjusted to about the center of the dynamic range of the A/D converter 51.

In this case, the conditions R5=R1, R6=R2, and R3±R4 are set. If the conditions Vdc′=Vdc×R1/(R1+R2) and Vac′=Vac×R1/(R1+R2) are set, a voltage A/Din input to the A/D converter is represented by the following simplified Equation 3.

A/Din=VD−VC=2×(Vdc′+Vac′)−Vdc′=Vdc′+2×Vac′ (3)

In Equation 3, even when the amplitude of the DC component is reduced by the resistance voltage division, the amplitude of the AC component is not reduced. As a result, the AC component is measured as a value larger than that of the DC component. Similar to the above-described characteristic P, the voltage measuring module 43b is designed such that the gain of the DC component of the supply voltage becomes one time and the gain of the AC component of the supply voltage becomes larger than one time.

A pass band of the LPF 53 has a DC component, but does not have a frequency component of the power ripple. The pass band (cutoff frequency) of the LPF 53 may be determined in consideration of a resonance frequency of the laminated ceramic capacitor, a resonance frequency of the shock sensor, and a resonance frequency of the PCBA.

Any circuit that subtracts a signal obtained by attenuating the AC component from the supply voltage signal may be used as the configuration other than the voltage measuring module 43b.

As described above, according to the first and second embodiments, as illustrated in Equation 2 or 3, if the line ripple (AC component) is extracted and amplified, the AC component can be read without being suppressed, and the line ripple detection performance can be prevented from being deteriorated due to the reduction of the dynamic range. By this, the lowering of the shock detection precision for the purpose of preventing the erroneous detection of the shock does not need to be performed.

Moreover, a DC component and an AC component of an input voltage signal can be detected with high accuracy.

The voltage measuring device of the embodiments can be easily applied to the storage device. The storage device may be a magnetic storage device, an optical storage device, or a magneto-optical storage device. The magnetic storage device may be a magnetic disk device or a magnetic tape device.

The various modules of the systems described herein can be implemented as software applications, hardware and/or software modules, or components on one or more computers, such as servers. While the various modules are illustrated separately, they may share some or all of the same underlying logic or code.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A voltage measuring device that measures an input voltage signal, comprising:
a divider configured to divide the input voltage signal into a first signal and a second signal;
a filter configured to attenuate a direct current component of the first signal in a predetermined range of frequency components of an alternating current component of the first signal;
an adder configured to add an output signal of the filter to the second signal; and
an analog-to-digital converter configured to convert an output signal of the adder into a digital signal,
wherein the divider is configured to adjust an amplitude of at least one of the first signal and the second signal in such a manner that a direct current component of the output signal of the adder is in an input range of the analog-to-digital converter.

2. The voltage measuring device of claim 1, wherein the divider is configured to adjust the amplitude of at least one of the first signal and the second signal in such a manner that the amplitude of the second signal is smaller than the amplitude of the first signal.

3. The voltage measuring device of claim 2, wherein the divider is configured to attenuate the amplitude of the second signal in such a manner that the amplitude of the second signal is smaller than amplitude of the input voltage signal.

4. The voltage measuring device of claim 1, wherein the divider is configured to adjust the amplitude of at least one of the first signal and the second signal by resistance voltage division.

5. The voltage measuring device of claim 1, wherein the adder is configured to amplify the output signal of the filter and to add the output signal to the second signal.

6. The voltage measuring device of claim 1, wherein the filter is configured to pass the predetermined range of frequency component of the alternating current component of the first signal and to remove the direct current component of the first signal.

7. A voltage measuring device that measures an input voltage signal, comprising:
a divider configured to divide the input voltage signal into a third signal and a fourth signal;
a filter configured to attenuate a predetermined range of frequency component of an alternating current component of the third signal in a direct current component of the third signal;
a subtracter configured to subtract an output signal of the filter from the fourth signal; and
an analog-to-digital converter configured to convert an output signal of the subtracter into a digital signal,
wherein the divider is configured to adjust an amplitude of at least one of the third signal and the fourth signal in such a manner that a direct current component of the output signal of the subtracter is in an input range of the analog-to-digital converter.

8. The voltage measuring device of claim 7, wherein the divider is configured to adjust the amplitude of at least one of the third signal and the fourth signal in such a manner that the amplitude of the third signal is smaller than the amplitude of the fourth signal.

9. The voltage measuring device of claim 7, wherein the divider is configured to adjust the amplitude of at least one of the third signal and the fourth signal in such a manner that the amplitude of the predetermined range of frequency component of the fourth signal is twice the amplitude of a direct current component of the output signal of the filter.

10. The voltage measuring device of claim 7, wherein the divider is configured to attenuate the amplitude of the third signal in such a manner that the amplitude of the third signal is smaller than the amplitude of the input voltage signal.

11. The voltage measuring device of claim 7, wherein the filter is configured to pass the direct current component of the third signal and to remove the predetermined range of frequency component of the alternating current component of the third signal.

12. The voltage measuring device of claim 7, wherein the divider is configured to adjust the amplitude of at least one of the third signal and the fourth signal by resistance voltage division.

13. A storage device that performs a write operation on a storage medium, comprising:
a divider configured to divide an input voltage signal supplied to the storage device into a first signal and a second signal;
a filter configured to attenuate a direct current component of the first signal in a predetermined range of frequency component of an alternating current component of the first signal;
an adder configured to add an output signal of the filter to the second signal;
an analog-to-digital converter configured to convert an output signal of the adder into a digital signal;
a shock sensor configured to detect a shock applied to the storage device; and
a controller configured to control the write operation on the storage medium based on an output from the analog-to-digital converter and an output from the shock sensor,
wherein the divider is configured to adjust amplitude of at least one of the first signal and the second signal in such a manner that a direct current component of the output signal of the adder is in an input range of the analog-to-digital converter.

14. The storage device of claim 13, wherein the controller is configured to detect position of a head configured to perform the write operation on the storage medium, and to control the write operation on the storage medium based on the output from the analog-to-digital converter, the output from the shock sensor, and the position.
